(19) United States
(12) Patent Application Publication
(10) Pub. No.: US 2023/0245881 A1
(43) Pub. Date: Aug. 3, 2023

(54) FILM FORMING METHOD AND FILM FORMING APPARATUS

(71) Applicant: Tokyo Electron Limited, Minato-ku, Tokyo (JP)

(72) Inventors: Zeyuan NI, Nirasaki-shi, Yamanashi (JP); Taiki KATO, Nirasaki-shi, Yamanashi (JP)

(21) Appl. No.: 18/004,931

(22) PCT Filed: Jul. 2, 2021
(86) PCT No.: PCT/JP2021/025163

§ 371 Date: Jan. 10, 2023

(30) Foreign Application Priority Data
Jul. 13, 2020 (JP) 2020-120193

(51) Int. Cl. H01L 21/02; C08F 20/44; C09D 133/20; C09D 155/02; C23C 16/40; C23C 16/455; C23C 16/34

(52) U.S. Cl. CPC H01L 21/02118; C08F 20/44; C09D 133/20; C09D 155/02; C23C 16/345; C23C 16/403; C23C 16/45536

(57) ABSTRACT

A film forming method includes the following (A) to (D). (A) Preparing a substrate having a first region in which a metal film is exposed and a second region in which an insulating film is exposed. (B) Supplying an organic compound, which is represented by Chemical Formula (1) described in the specification, to the substrate, the organic compound containing a triple bond between a carbon atom and a nitrogen atom in a head group and containing a double bond or triple bond between carbon atoms in a chain. (C) Selectively adsorbing the organic compound to the first region among the first region and the second region. (D) Polymerizing adjacent chains of the organic compound, thereby forming a polymer film in the first region.

### TECHNICAL FIELD

The present disclosure relates to a film forming method and a film forming apparatus.

### BACKGROUND

Patent Document 1 discloses molecules that form a self-assembled monolayer (SAM). The molecules are, for example, thiols or nitriles, and are selectively adsorbed to metal surfaces or semiconductor surfaces.

### PRIOR ART DOCUMENT

### Patent Document

Patent Document 1: U.S. Pat. Application Publication No. 2007/0014998

One aspect of the present disclosure provides a technique for selectively coating a metal film surface, among the metal film surface and an insulating film surface, with an organic compound, and improving the coverage thereof.

### SUMMARY

A film forming method according to an aspect of the present disclosure includes the following (A) to (D). (A) Preparing a substrate having a first region in which a metal film is exposed and a second region in which an insulating film is exposed. (B) Supplying an organic compound represented by the following Chemical Formula (1) to the substrate, the organic compound containing a triple bond between a carbon atom and a nitrogen atom in a head group and containing a double bond or triple bond between carbon atoms in a chain. (C) Selectively adsorbing the organic compound to the first region among the first region and the second region. (D) Polymerizing adjacent chains of the organic compound, thereby forming a polymer film in the first region.

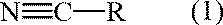

In the above Chemical Formula (1), R is a functional group including a double bond or triple bond between carbon atoms.

According to an aspect of the present disclosure, it is possible to selectively coat a metal film surface, among the metal film surface and an insulating film surface, with an organic compound, and to improve the coverage thereof.

### BRIEF DESCRIPTION OF DRAWINGS

FIG. 1 is a flowchart illustrating a film forming method according to an embodiment.

FIG. 2A is a diagram illustrating an example of S1 in FIG. 1.

FIG. 2B is a diagram illustrating an example of S2 in FIG. 1.

FIG. 2C is a diagram illustrating an example of S3 in FIG. 1.

FIG. 2D is a diagram illustrating an example of S4 in FIG. 1.

FIG. 3 is a diagram illustrating an example of a film forming method that uses acrylonitrile as an organic compound.

FIG. 4 is a diagram illustrating an example of a film forming method that uses acrylonitrile as an organic compound and uses 1,3-butadiene as a second organic compound.

FIG. 5 is a diagram illustrating an example of a film forming method that uses radicals of an organic peroxide.

FIG. 6 is a plan view illustrating a film forming apparatus according to an embodiment.

FIG. 7 is a cross-sectional view illustrating an example of a first processor of FIG. 6.

### DETAILED DESCRIPTION

Hereinafter, embodiment of the present disclosure will be described with reference to the accompanying drawings. In addition, in each drawing, the same reference numerals will be given to the same or corresponding components, and descriptions thereof may be omitted.

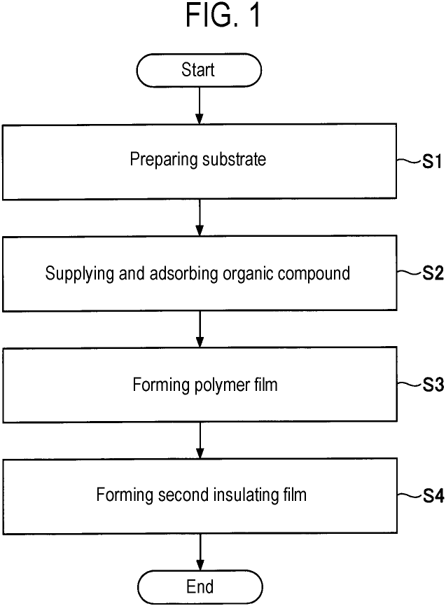

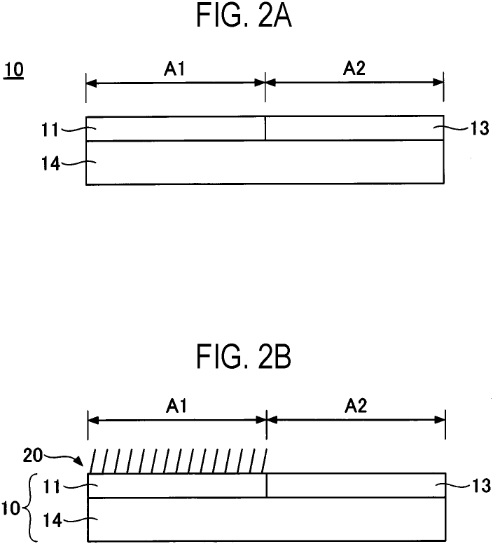

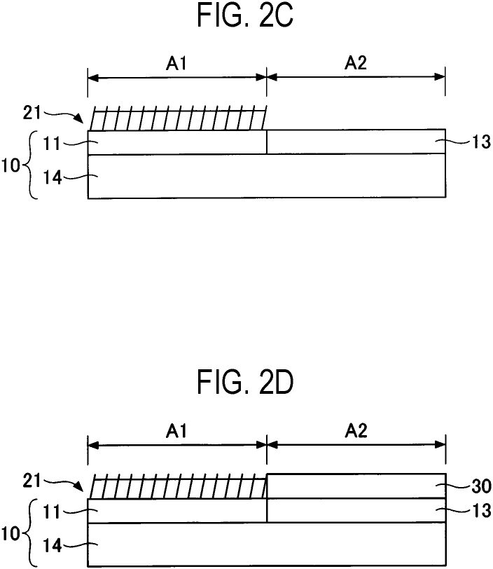

First, a film forming method according to an embodiment will be described with reference to FIGS. 1 and 2A to 2D. The film forming method of the present embodiment includes steps S1 to S4 illustrated in FIG. 1. In addition, although details will be described later, the film forming method may further include step(s) other than steps S1 to S4.

In step S1, as illustrated in FIG. 2A, a substrate 10 is prepared. Preparation of the substrate 10 includes, for example, placing the substrate 10 inside a processing container 210 to be described later. The substrate 10 has a first region A1 in which a metal film 11 is exposed and a second region A2 in which an insulating film 13 is exposed.

The number of first regions A1 is one in FIG. 2A, but may be plural. For example, two first regions A1 may be arranged so as to sandwich the second region A2 therebetween. Similarly, the number of second regions A2 is one in FIG. 2A, but may be plural. For example, two second regions A2 may be arranged so as to sandwich the first region A1 therebetween.

In addition, although only the first region A1 and the second region A2 exist in FIG. 2A, a third region may further exist. The third region is a region in which a film formed of a material different from those of the first region A1 and the second region A2 is exposed. The third region may be arranged between the first region A1 and the second region A2, or may be arranged outside the first region A1 and the second region A2.

The material of the metal film 11 is, for example, a transition metal. An example of the transition metal is Cu, W, Co, Ru, or Ni. The metal film 11 is normally oxidized naturally in the atmosphere. As a result, the surface of the metal film 11 may be covered with an oxide coating film (not illustrated). In this case, step S1 includes removing the oxide coating film.

Removal of the oxide coating film includes, for example, supplying a hydrogen (H₂) gas to the substrate 10. The hydrogen gas reduces and removes the oxide coating film. The hydrogen gas may be heated to a high temperature, in order to promote a chemical reaction. Further, the hydrogen gas may be formed into plasma, in order to promote a chemical reaction.

The supply of the hydrogen gas is performed, for example, at a temperature of 200° C. or more and 400 degrees or less and an atmospheric pressure of 0.5 Torr or more and 760 Torr or less for a period of 2 minutes or more and 60 minutes or less. The hydrogen gas may be diluted with an inert gas such as an argon gas, and the concentration of the hydrogen gas may be 10 mass% or more and 100 mass% or less.

The removal of the oxide coating film is a dry processing in the present embodiment, but may be a wet processing. For example, the removal of the oxide coating film may include supplying citric acid to the substrate 10. The substrate 10 may be immersed in citric acid, or may be spin-cleaned with citric acid.

The processing with citric acid is performed, for example, at a temperature of 25° C. or more and 60° C. or less for a period of 10 seconds or more and 5 minutes or less. Citric acid may be supplied in the form of an aqueous solution, and the concentration of citric acid may be 0.5 mass% or more and 10 mass% or less.

On the other hand, the material of the insulating film 13 is, for example, a metal compound. The metal compound is an aluminum oxide, silicon oxide, silicon nitride, silicon oxynitride, silicon oxycarbide, silicon carbide, or the like. The material of the insulating film 13 may be a low dielectric constant material (Low-k material) having a dielectric constant lower than that of SiO₂.

The substrate 10 includes a base substrate 14, in addition to the metal film 11 and the insulating film 13. The base substrate 14 is, for example, a semiconductor substrate such as a silicon wafer. In addition, the base substrate 14 may be a glass substrate, or the like. The metal film 11 and the insulating film 13 are formed on the surface of the base substrate 14.

In addition, the substrate 10 may further include a base film, formed of a material different from those of the base substrate 14 and the insulating film 13, between the base substrate 14 and the insulating film 13. Similarly, the substrate 10 may further include a base film, formed of a material different from those of the base substrate 14 and the metal film 11, between the base substrate 14 and the metal film 11.

In step S2, as illustrated in FIG. 2B, the organic compound 20 represented by the following Chemical Formula (1), which contains a triple bond between a carbon atom and a nitrogen atom in a head group, and also contains a double bond or triple bond between carbon atoms in a chain, is supplied to the substrate 10. In step S2, the organic compound 20 is selectively adsorbed to the first region A1 among the first region A1 and the second region A2. A self-assembled monolayer containing the organic compound 20 is selectively formed in the first region A1.

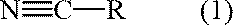

In the Chemical Formula (1), R is a functional group containing a double bond or triple bond between carbon atoms. R is an unsaturated hydrocarbon group. R is preferably a straight chain. The straight chain has a structure in which carbon atoms are arranged in a straight line without branching and without forming a ring. The longer the straight chain, the higher the hydrophobicity.

In the Chemical Formula (1), R is, for example, [CH₂]ₙ—CH═CH—[CH₂]ₘ—H. Here, n and m are natural numbers equal to or greater than zero. When the organic compound 20 is acrylonitrile (C₃H₃N), n and m are zero.

In addition, in the Chemical Formula (1), R may be a functional group in which a hydrogen atom of an unsaturated hydrocarbon group is substituted with a halogen atom. The halogen atom is not particularly limited, but is, for example, a fluorine atom.

The organic compound 20 is nitrile and contains a triple bond between a carbon atom and a nitrogen atom in a head group. The head group has a property that it is difficult to be adsorbed to the substrate surface having an OH group. The metal film 11 is exposed in the first region A1, whereas the insulating film 13 is exposed in the second region A2. In general, the metal film 11 has almost no OH group on the surface thereof, whereas the insulating film 13 has an OH group on the surface thereof. Thus, the head group is selectively adsorbed to the first region A1 among the first region A1 and the second region A2. The ease of adsorption is represented by the absolute value |ΔE| of adsorption energy ΔE.

The adsorption energy ΔE is obtained, for example, from the formula ΔE=Ea-Eb. Ea is the energy of the organic compound 20 in a state where it is adsorbed to the substrate surface, and Eb is the energy of the organic compound 20 in a free state where it is spaced apart from the substrate surface.

The adsorption energy ΔE is obtained by first-principles calculation and is obtained by simulation. The larger the absolute value |ΔE| of the adsorption energy ΔE, the easier the organic compound 20 is adsorbed to the substrate surface.

In this specification, |ΔE| on the surface of the metal film 11 is called |ΔE1|, and |ΔE| on the surface of the insulating film 13 is called |ΔE2|. |ΔE1| is sufficiently large compared to |ΔE2|. For example, when the organic compound 20 is lactonitrile, the material of the metal film 11 is Cu and the material of the insulating film 13 is either a silicon oxide or an aluminum oxide, |ΔE1-ΔE2| is about 0.9 eV to 1.3 eV.

By the way, similarly to the organic compound 20, a thiol-based compound is also selectively adsorbed to the first region A1 among the first region A1 and the second region A2. The thiol-based compound contains hydrogenated sulfur in a head group and is represented by the chemical formula “R-SH″. In the case of the thiol-based compound, when the material of the metal film 11 is Cu and the material of the insulating film 13 is either a silicon oxide or an aluminum oxide, |ΔE1-ΔE2| is about 1.0 eV.

On the other hand, in the case of the organic compound 20, when the material of the metal film 11 is Cu and the material of the insulating film 13 is either a silicon oxide or an aluminum oxide, |ΔE1-ΔE2| is about 0.9 eV to 1.3 eV as described above. Accordingly, the organic compound 20 may have excellent selectivity even compared to the thiol-based compound since it may be selectively adsorbed to the first region A1.

The organic compound 20 is supplied to the substrate 10, for example, in a gaseous state. In addition, the organic compound 20 may be supplied to the substrate 10 in a liquid state. In that case, the organic compound 20 may be supplied to the substrate 10 in a state where it is dissolved in a solvent, and, for example, may be applied to the substrate 10 by a spin coating method or the like. When the organic compound 20 is supplied to the substrate 10 in a liquid state, the solvent is volatilized and the substrate 10 is dried before step S4.

In step S3, as illustrated in FIG. 2C, adjacent chains of the organic compound 20 are polymerized, thereby forming a polymer film 21 in the first region A. R, which is a chain of the organic compound 20, contains a double bond or triple bond between carbon atoms, and polymerization progresses as the double bond or triple bond is opened. A gap between the adjacent chains of the organic compound 20 may be covered by polymerization, which may improve the coverage of the first region A1. As a result, in step S4 to be described later, the formation of a second insulating film 30 in the first region A1 may be inhibited, which may allow the second insulating film 30 to be more selectively formed in the second region A2.

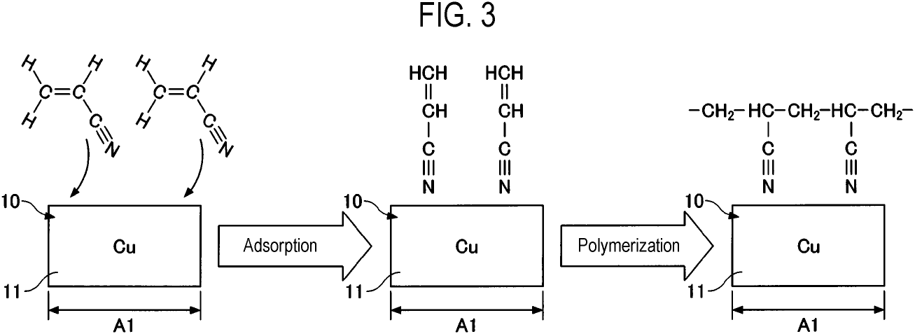

Here, an example of a film forming method that uses acrylonitrile as the organic compound 20 will be described with reference to FIG. 3. As illustrated in FIG. 3, when acrylonitrile is supplied to the substrate 10, a head group of acrylonitrile is selectively adsorbed to the first region A1. Thereafter, adjacent chains of acrylonitrile are polymerized. As a result, the polymer film 21 is formed.

However, in step S3, an additive other than the organic compound 20 may be supplied to the substrate 10, in order to promote a polymerization reaction between chains of the organic compound 20. For example, a second organic compound may be supplied to the substrate 10 in step S3. The second organic compound is different from the organic compound 20. The polymer film 21 is formed by copolymerization of the organic compound 20 and the second organic compound.

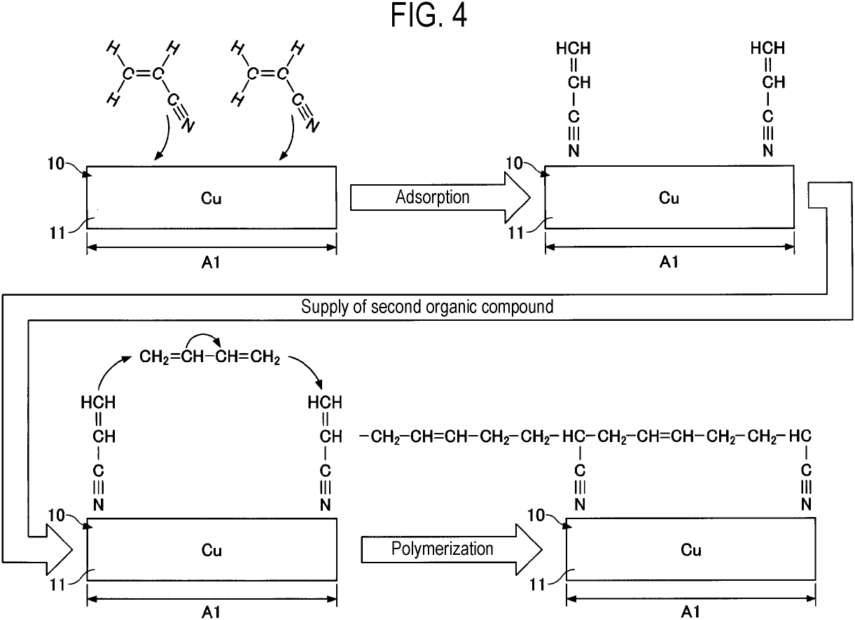

Here, an example of a film forming method that uses acrylonitrile as the organic compound 20 and uses 1,3-butadiene (CH₂═CH—CH═CH₂) as the second organic compound will be described with reference to FIG. 4. As illustrated in FIG. 4, when acrylonitrile is supplied to the substrate 10, a head group of acrylonitrile is selectively adsorbed to the first region A1. Thereafter, 1,3-butadiene is supplied to the substrate 10, and a nitrile rubber is produced by copolymerization of acrylonitrile and 1,3-butadiene. The polymer film 21 containing the nitrile rubber is formed.

The second organic compound is supplied to the substrate 10 in a gaseous state, for example. In addition, the second organic compound may be supplied to the substrate 10 in a liquid state. In that case, the second organic compound may be supplied to the substrate 10 in a state where it is dissolved in a solvent, and, for example, may be applied to the substrate 10 by a spin coating method or the like. The solvent is not particularly limited, but is, for example, tetrahydrofuran (THF). When the second organic compound is supplied to the substrate 10 in a liquid state, the solvent is volatilized and the substrate W is dried before step S4 to be described later.

In step S3, furthermore, a third organic compound may be supplied to the substrate 10. The third organic compound is different from the organic compound 20 and the second organic compound. The polymer film 21 may be formed by copolymerization of the organic compound 20, the second organic compound, and the third organic compound.

Although not illustrated, when acrylonitrile is used as the organic compound 20, 1,3-butadiene is used as the second organic compound, and styrene is used as the third organic compound, an ABS resin is produced by copolymerization of these. The polymer film 21 containing the ABS resin is formed.

In step S3, a polymerization initiator may be supplied as an additive to the substrate 10. For example, azobisisobutyronitrile (AIBN) may be used as a polymerization initiator for copolymerization to produce the ABS resin. Further, in step S3, a catalyst may be supplied as an additive to the substrate 10, in order to promote a polymerization reaction.

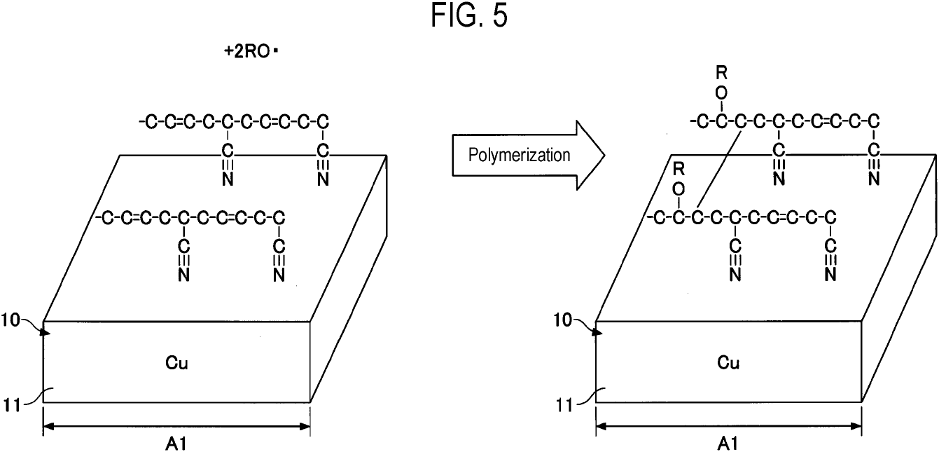

Further, in step S3, a crosslinking agent may be supplied as an additive to the substrate 10. For example, as illustrated in FIG. 5, an organic peroxide may be used as the crosslinking agent. The organic peroxide has a peroxy group (—O—O—) and generates free radicals in the form of RO. These radicals may increase the degree of polymerization of the polymer film 21. In FIG. 5, the linking of nitrile rubbers progresses by the radicals.

Step S3 is not particularly limited, but is performed, for example, at a temperature of 5 degree C or more and 200° C. or less, preferably, at a temperature of 5 degree C or more and 80° C. or less and an atmospheric pressure of 0.1 Torr or more and 300 Torr or less. The film forming conditions of step S3 are suitably determined according to the kind of the organic compound 20 or the like.

In step S3, the substrate 10 may be irradiated with light that promotes polymerization of adjacent chains of the organic compound 20. The light to be irradiated is, for example, ultraviolet rays or infrared rays. The time required to form the polymer film 21 may be shortened by the irradiation of light. Further, the irradiation of light enables the formation of the polymer film 21 at a low temperature.

In step S4, as illustrated in FIG. 2D, the second insulating film 30 is selectively formed in the second region A2, among the first region A1 and the second region A2, using the polymer film 21. Since the polymer film 21 inhibits the formation of the second insulating film 30, the second insulating film 30 is selectively formed in the second region A2.

The second insulating film 30 is formed by, for example, a chemical vapor deposition (CVD) method or an atomic layer deposition (ALD) method. The second insulating film 30 can be stacked on the insulating film 13 which is originally present in the second region A2.

The second insulating film 30 is not particularly limited, but is formed of, for example, an aluminum oxide. Hereinafter, an aluminum oxide is also referred to as “A1O” regardless of the composition ratio of oxygen and aluminum. When an AlO film is formed as the second insulating film 30 by the ALD method, an Al-containing gas such as a trimethylaluminum (TMA: (CH₃)₃Al) gas and an oxidizing gas such as water vapor (H₂O gas) are alternately supplied as processing gases to the substrate 10. Since water vapor is not adsorbed to the polymer film 21, AlO is selectively deposited in the second region A2. In addition to the Al-containing gas and the oxidizing gas, a modification gas such as a hydrogen (H₂) gas may be supplied to the substrate 10. These processing gases may be formed into plasma, in order to promote a chemical reaction. Further, these processing gases may be heated, in order to promote a chemical reaction.

Further, the second insulating film 30 may be formed of a silicon oxide. Hereinafter, a silicon oxide is also referred to as “SiO” regardless of the composition ratio of oxygen and silicon. When a SiO film is formed as the second insulating film 30 by the ALD method, a Si-containing gas such as a dichlorosilane (SiH₂Cl₂) gas and an oxidizing gas such as an ozone (O₃) gas are alternately supplied as processing gases to the substrate 10. In addition to the Si-containing gas and the oxidizing gas, a modification gas such as a hydrogen (H₂) gas may be supplied to the substrate 10. These processing gases may be formed into plasma, in order to promote a chemical reaction. Further, these processing gases may be heated, in order to promote a chemical reaction.

Further, the second insulating film 30 may be formed of a silicon nitride. Hereinafter, a silicon nitride is also referred to as “SiN” regardless of the composition ratio of nitrogen and silicon. When a SiN film is formed as the second insulating film 30 by the ALD method, a Si-containing gas such as a dichlorosilane (SiH₂Cl₂) gas and a nitriding gas such as an ammonia (NH₃) gas are alternately supplied to the substrate 10. In addition to the Si-containing gas and the nitriding gas, a modification gas such as a hydrogen (H₂) gas may be supplied to the substrate 10. These processing gases may be formed into plasma, in order to promote a chemical reaction. Further, these processing gases may be heated, in order to promote a chemical reaction.

In addition, the film forming method may further include steps other than steps S1 to S4 illustrated in FIG. 1. For example, the film forming method may include a step of modifying the polymer film 21 between step S3 and step S4. Further, the film forming method may include a step of removing the excess organic compound 20 or the like, which is not adsorbed to the substrate 10, between step S3 and step S4.

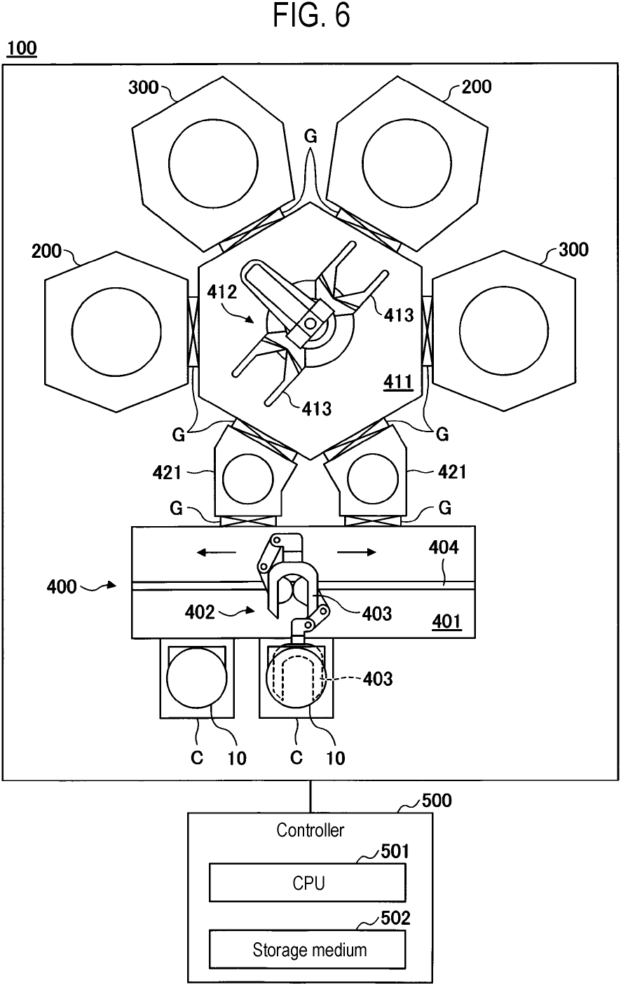

Next, a film forming apparatus 100 for performing the above film forming method will be described with reference to FIG. 6. As illustrated in FIG. 6, the film forming apparatus 100 includes a first processor 200, a second processor 300, a transporter 400, and a controller 500. The first processor 200 selectively adsorbs the organic compound 20 to the first region A1 among the first region A1 and the second region A2, and polymerizes adjacent chains of the organic compound 20, thereby forming the polymer film 21. The second processor 300 selectively forms the second insulating film 30 in the second region A2, among the first region A1 and the second region A2, using the polymer film 21 formed by the first processor 200. The transporter 400 transports the substrate 10 to the first processor 200 and the second processor 300. The controller 500 controls the first processor 200, the second processor 300, and the transporter 400.

The transporter 400 includes a first transport chamber 401 and a first transport mechanism 402. The internal atmosphere of the first transport chamber 401 is an air atmosphere. The first transport mechanism 402 is provided inside the first transport chamber 401. The first transport mechanism 402 has an arm 403 configured to hold the substrate 10, and travels along a rail 404. The rail 404 extends in the direction in which carriers C are arranged.

Further, the transporter 400 includes a second transport chamber 411 and a second transport mechanism 412. The internal atmosphere of the second transport chamber 411 is a vacuum atmosphere. The second transport mechanism 412 is provided inside the second transport chamber 411. The second transport mechanism 412 has an arm 413 configured to hold the substrate 10, and the arm 413 is arranged to be movable in the vertical and horizontal directions and to be rotatable about the vertical axis. The first processor 200 and the second processor 300 are connected to the second transport chamber 411 via different gate valves G.

Furthermore, the transporter 400 includes a load lock chamber 421 between the first transport chamber 401 and the second transport chamber 411. The internal atmosphere of the load lock chamber 421 is switched between a vacuum atmosphere and an air atmosphere by a pressure regulating mechanism (not illustrated). Thereby, the inside of the second transport chamber 411 may always be maintained in the vacuum atmosphere. Further, the flow of a gas from the first transport chamber 401 to the second transport chamber 411 may be prevented. Gate valves G are provided between the first transport chamber 401 and the load lock chamber 421 and between the second transport chamber 411 and the load lock chamber 421.

The controller 500 is, for example, a computer, and includes a central processing unit (CPU) 501 and a storage medium 502 such as a memory. The storage medium 502 stores a program for controlling various processings executed in the film forming apparatus 100. The controller 500 controls an operation of the film forming apparatus 100 by causing the CPU 501 to execute the program stored in the storage medium 502. The controller 500 controls the first processor 200, the second processor 300, and the transporter 400 to perform the above substrate processing method.

Next, an operation of the film forming apparatus 100 will be described. First, the first transport mechanism 402 extracts the substrate 10 from the carrier C, transports the extracted substrate 10 to the load lock chamber 421, and is retracted from the load lock chamber 421. Next, the internal atmosphere of the load lock chamber 421 is switched from the air atmosphere to the vacuum atmosphere. Thereafter, the second transport mechanism 412 extracts the substrate 10 from the load lock chamber 421 and transports the extracted substrate 10 to the first processor 200.

Next, the first processor 200 performs steps S2 and S3. That is, the first processor 200 selectively adsorbs the organic compound 20 to the first region A1 among the first region A1 and the second region A2, and polymerizes adjacent chains of the organic compound 20, thereby forming the polymer film 21. A gap between the adjacent chains of the organic compound 20 can be covered, which may improve the coverage of the first region A1. As a result, in step S4 to be described later, the formation of the second insulating film 30 in the first region A1 can be inhibited, which may allow the second insulating film 30 to be more selectively formed in the second region A2.

Next, the second transport mechanism 412 extracts the substrate 10 from the first processor 200 and transports the extracted substrate 10 to the second processor 300. During this time, the atmosphere around the substrate 10 may be maintained in a vacuum atmosphere, which can prevent a deterioration in the blocking performance of the polymer film 21.

Next, the second processor 300 performs step S4. That is, the second processor 300 selectively form the second insulating film 30 in the second region A2, among the first region A1 and the second region A2, using the polymer film 21 formed by the first processor 200.

Next, the second transport mechanism 412 extracts the substrate 10 from the second processor 300, transports the extracted substrate 10 to the load lock chamber 421, and is retracted from the load lock chamber 421. Subsequently, the internal atmosphere of the load lock chamber 421 is switched to the air atmosphere from the vacuum atmosphere. Thereafter, the first transport mechanism 402 extracts the substrate 10 from the load lock chamber 421 and accommodates the extracted substrate 10 in the carrier C.

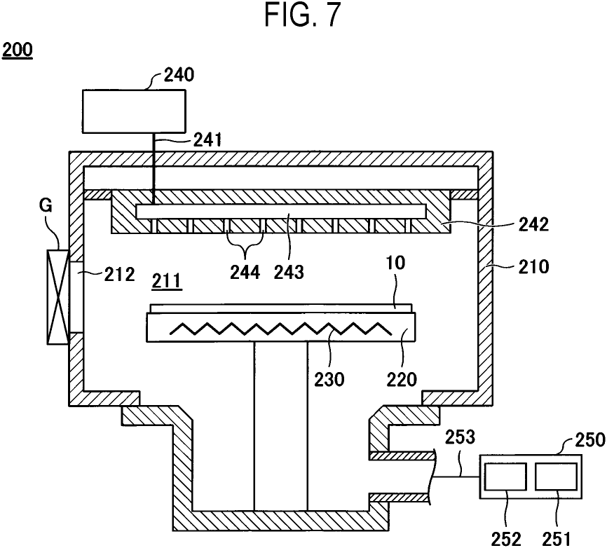

Next, the first processor 200 will be described with reference to FIG. 7. In addition, since the second processor 300 is configured in the same manner as the first processor 200, illustration and description thereof will be omitted.

The first processor 200 includes the processing container 210, a substrate holder 220, a temperature regulator 230, a gas supply 240, and a gas discharger 250. The processing container 210 accommodates the substrate 10. The substrate holder 220 holds the substrate 10 inside the processing container 210. The temperature regulator 230 regulates the temperature of the substrate 10. The gas supply 240 supplies a gas to the inside of the processing container 210. The gas contains vapor of the organic compound 20. Furthermore, the gas may contain vapor of the second organic compound. The gas discharger 250 discharges the gas from the inside of the processing container 210.

The processing container 210 has a loading/unloading port 212 for the substrate 10. A gate valve G is provided at the loading/unloading port 212 to open and close the loading/unloading port 212. The gate valve G basically closes the loading/unloading port 212, and opens the loading/unloading port 212 when the substrate 10 passes through the loading/unloading port 212. A processing chamber 211 inside the processing container 210 communicates with the second transport chamber 411 while the loading/unloading port 212 is opened.

The substrate holder 220 holds the substrate 10 inside the processing container 210. The substrate holder 220 horizontally holds the substrate 10 from below so that the surface of the substrate 10, which is exposed to vapor of the organic compound 20 or the like, faces upward. The substrate holder 220 is of a single wafer type and holds one substrate 10. In addition, the substrate holder 220 may be of a batch type and may hold a plurality of substrates 10 at the same time. The batch type substrate holder 220 may hold the plurality of substrates 10 at intervals in the vertical direction, or may hold the plurality of substrates 10 at intervals in the horizontal direction.

The temperature regulator 230 regulates the temperature of the substrate 10. The temperature regulator 230 includes, for example, an electric heater. The temperature regulator 230 is, for example, embedded in the substrate holder 220, and heats the substrate 10 to a desired temperature by heating the substrate holder 220. In addition, the temperature regulator 230 may include a lamp that heats the substrate holder 220 through a quartz window. In this case, an inert gas such as an argon gas may be supplied between the substrate holder 220 and the quartz window, in order to prevent the quartz window from becoming opaque with deposits. In addition, the temperature regulator 230 may be provided outside the processing container 210 to regulate the temperature of the substrate 10 from the outside of the processing container 210.

The gas supply 240 supplies a preset gas to the substrate 10. The gas supply 240 is connected to the processing container 210 via, for example, a gas supply pipe 241. The gas supply 240 includes a gas supply source, an individual pipe extending individually from each supply source to the gas supply pipe 241, an on/off valve provided in the middle of the individual pipe, and a flow rate controller provided in the middle of the individual pipe. When the on/off valve opens the individual pipe, a gas is supplied from the supply source to the gas supply pipe 241. The amount of the supplied gas is controlled by the flow rate controller. On the other hand, when the on/off valve closes the individual pipe, the supply of the gas from the supply source to the gas supply pipe 241 is stopped.

The gas supply pipe 241 supplies the gas supplied from the gas supply 240 to the inside of the processing container 210. The gas supply pipe 241 supplies the gas supplied from the gas supply 240 to a shower head 242, for example. The shower head 242 is provided above the substrate holder 220. The shower head 242 has a space 243 therein, and discharges the gas stored in the space 243 vertically downward from a large number of gas discharge holes 244. A shower of gas is supplied to the substrate 10.

The gas discharger 250 discharges the gas from the inside of the processing container 210. The gas discharger 250 is connected to the processing container 210 via an exhaust pipe 253. The gas discharger 250 includes an exhaust source 251 such as a vacuum pump and a pressure controller 252. When the exhaust source 251 is operated, the gas is discharged from the inside of the processing container 210. The atmospheric pressure inside the processing container 210 is controlled by the pressure controller 252.

In addition, S2, S3, and S4 illustrated in FIG. 1 may be performed inside the same processing container 210, or may be performed inside different processing containers 210. That is, S2, S3, and S4 illustrated in FIG. 1 may be performed by the same processor, or may be performed by different processors.

Although the embodiment of the film forming method and the film forming apparatus according to the present disclosure have been described above, the present disclosure is not limited to the above embodiments. Various changes, modifications, substitutions, additions, deletions, and combinations are possible within the scope set forth in the claims. These also naturally belong to the technical scope of the present disclosure.

This application claims priority based on Japanese Patent Application No. 2020-120193 filed on Jul. 13, 2020 to the Japan Patent Office, and the entirety of Japanese Patent Application No. 2020-120193 is incorporated in this application.

### EXPLANATION OF REFERENCE NUMERALS

10: substrate, 11: metal film, 13: insulating film, 20: organic compound, 21: polymer film

1-10. (canceled)

11. A film forming method comprising:
preparing a substrate having a first region in which a metal film is exposed and a second region in which an insulating film is exposed;
supplying an organic compound represented by the following Chemical Formula (1) to the substrate, the organic compound containing a triple bond between a carbon atom and a nitrogen atom in a head group and containing a double bond or triple bond between carbon atoms in a chain;
selectively adsorbing the organic compound to the first region among the first region and the second region; and
polymerizing adjacent chains of the organic compound in the first region to form a polymer film, wherein, 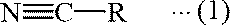
the Chemical Formula (1), R is a functional group containing a double bond or triple bond between carbon atoms.

12. The method of claim 11, wherein the chain is an unsaturated hydrocarbon group, or a functional group obtained by substituting a carbon atom of the unsaturated hydrocarbon group with a fluorine atom.

13. The method of claim 12, wherein a second organic compound different from the organic compound is supplied to the substrate, and the polymer film is formed by copolymerization of the organic compound and the second organic compound.

14. The method of claim 13, wherein the organic compound is acrylonitrile, and the second organic compound is 1,3-butadiene.

15. The method of claim 14, wherein the metal film is a copper film.

16. The method of claim 15, wherein the insulating film is an aluminum oxide film, a silicon oxide film, or a silicon oxynitride film.

17. The method of claim 16, further comprising selectively forming a second insulating film in the second region, among the first region and the second region, using the polymer film.

18. The method of claim 11, wherein a second organic compound different from the organic compound is supplied to the substrate, and the polymer film is formed by copolymerization of the organic compound and the second organic compound.

19. The method of claim 11, wherein a second organic compound different from the organic compound, and a third organic compound different from the organic compound and the second organic compound are supplied to the substrate, and the polymer film is formed by copolymerization of the organic compound, the second organic compound, and the third organic compound.

20. The method of claim 19, wherein the organic compound is acrylonitrile, the second organic compound is 1,3-butadiene, and the third organic compound is styrene.

21. The method of claim 11, wherein the metal film is a copper film.

22. The method of claim 11, wherein the insulating film is an aluminum oxide film, a silicon oxide film, or a silicon oxynitride film.

23. The method of claim 11, further comprising selectively forming a second insulating film in the second region, among the first region and the second region, using the polymer film.

24. A film forming apparatus comprising:
a processing container;
a substrate holder configured to hold a substrate inside the processing container;
a gas supply configured to supply a gas of an organic compound to an inside of the processing container;
a gas discharger configured to discharge the gas from the inside of the processing container;
a transporter configured to load and unload the substrate to and from the processing container; and
a controller configured to control the gas supply, the gas discharger, and the transporter to perform the film forming method according to claim 11.
